(19) United States
(12) Patent Application Publication
(10) Pub. No.: US 2005/0161079 A1
(43) Pub. Date: Jul. 28, 2005

(54) System and apparatus for charging an electronic device using solar energy

(76) Inventor: Randolph D. Gray, Round Rock, TX (US)

Correspondence Address: Kevin R. Imes, 2001 So. Mopac # 624, Austin, TX, 78746, US

(21) Appl. No.: 11/085,656

(22) Filed: Mar. 21, 2005

Related U.S. Application Data
(63) Continuation-in-part of application No. 10/292,248, filed on Nov. 12, 2002, now Pat. No. 6,870,089.

(51) Int. Cl. H01L 31/00

(52) U.S. Cl. 136/291; 136/293; 136/251

(57) ABSTRACT

A system and apparatus for charging an electronic device using solar energy are disclosed. In one form, an apparatus for charging an electronic device is provided. The apparatus includes a first charge port operable to be connected to an energy source and an energy repository operable to store energy provided by the energy source and to actively couple energy provided by the energy source to an electronic device. The apparatus further includes a second charge port operable to be connected to the electronic device to provide either the stored energy or the active energy to the electronic device.

### CROSS REFERENCE TO RELATED APPLICATION

This application is a Continuation-In-Part of application Ser. No. 10/292,248 filed Nov. 12, 2002 now U.S. Pat. No. 6,870,089 entitled “System and Apparatus for Charging an Electronic Device Using Solar Energy”.

### TECHNICAL FIELD

The present invention generally relates to energy consumption and, more particularly, to a system and apparatus for charging an electronic device using solar energy.

### BACKGROUND OF THE INVENTION

Power utilization of conventional hand-held electronic devices vary significantly depending on the application and utilization of a device. Some electronic devices include reduced power states that draw very little power when the electronic device is not in use. For example, a handheld computing device may use significantly more energy to process user inputs and display information within user interfaces such as thin film transistor active matrix displays (TFT displays). When the handheld computing device is not being used, it is placed in an off mode, sleep mode or other reduced power state to decrease or reduce power consumption.

Other electronic devices, such as some conventional cellular telephones, consume energy based on a user's interaction with a wireless network. For example, some conventional cellular telephones include off positions, standby modes for receiving phone calls or other incoming data services, and active mode for interacting with wireless networks to place and receive phone calls or requesting data services. Each mode of operation may have separate power demands or requirements.

Advancements in wireless networks may also increase power utilization of some electronic devices. For example, as cellular phones and handheld computing devices migrate to high speed wireless networks, power consumption of electronic devices may increase as a function of communicating and processing data via high-speed communication networks. This may result in more frequent charging of electronic devices.

### SUMMARY OF THE INVENTION

In accordance with teachings of the invention, an system and apparatus for charging an electronic device using solar energy are provided. According to one aspect of the invention, a portable storage apparatus for charging an electronic device is disclosed. The portable storage apparatus includes at least one solar panel integrated as a part of an exterior surface of a storage apparatus operable to store an electronic device and a conductive element electrically coupled between the at least one solar panel and a charge port. The charge port is operable to couple converted solar energy to charge a rechargeable battery of the electronic device.

According to another aspect of the invention, a portable solar charge system for charging an energy source associated with an electronic device is disclosed. The portable solar charge system includes a first solar panel securely coupled to an external portion of a storage apparatus and a second positional solar panel coupled to a portion of the storage apparatus. The system further includes at least one charge port electrically coupled to at least one of the first and second solar panels and operable to interface a conductive element to provide converted solar energy to charge the energy source.

According to a further aspect of the invention, a backpack operable to charge a battery associated with an electronic device is disclosed. The backpack includes a storage space for storing an electronic device and includes an interior portion and an exterior portion. The backpack further includes a first flexible solar panel integrated as a part of the exterior portion of the backpack and a second positional solar panel coupled to an interior portion of the backpack. The backpack further includes a universal twelve-volt charge port electrically coupled to the first and second solar panels. The universal twelve-volt charge port is operable to actively provide solar energy to charge the electronic device while the backpack is used within a mobile environment.

According to a further aspect of the invention, an apparatus for charging an electronic device comprising is disclosed. The apparatus includes a first charge port operable to be connected to an energy source and an energy repository operable to store energy provided by the energy source and to actively couple energy provided by the energy source to an electronic device. The apparatus further includes a second charge port operable to be connected to the electronic device to provide either the stored energy or the active energy to the electronic device.

According to a further aspect of the invention an apparatus for charging an electronic device is disclosed. The apparatus includes a first charge port operable to couple an electronic device to an energy source and a housing including electronics operable to couple the energy source to an energy repository and the electronic device.

According to a further aspect of the invention a portable energy repository operable to charge an electronic device is disclosed. The apparatus includes
a solar energy panel interface operable to couple converted solar energy to an electronic device. The apparatus further includes a rechargeable energy repository having at least one rechargeable battery operable to charge a first electronic device and a charge port operable to couple the converted solar energy to a second electronic device.

It is an object of the invention to provide an environmental friendly alternative energy resource for charging electronic devices.

It is another object of the invention to provide a portable charging system for electronic devices.

It is a further object of the invention to provide an efficient method to charge an electronic device in a mobile environment without requiring the use of conventional terrestrial energy sources.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of a portable storage apparatus having an integrated solar charge system according to one aspect of the invention;

FIG. 2 illustrates a block diagram of a portable storage apparatus having a solar charge system incorporating a universal charge port according to one aspect of the invention;

FIG. 3 illustrates a portable storage apparatus incorporating a solar charge system for charging an electronic device according to one aspect of the invention;

FIG. 4 illustrates a portable storage apparatus incorporating plural solar charge panels and charge ports according to one aspect of the invention;

FIG. 5 illustrates a thermal storage apparatus incorporating a solar charge system according to one aspect of the invention;

FIG. 6A illustrates a collapsible solar storage apparatus in an expanded position according to one aspect of the invention;

FIG. 6B illustrates a collapsible solar storage apparatus in a collapsed position incorporating a solar charge system according to one aspect of the invention;

FIG. 7 illustrates a block diagram of solar charge system according to one aspect of the invention;

FIG. 8A illustrates a diagram of a portable multi-port solar charge system in a closed position according to one aspect of the invention;

FIG. 8B illustrates a diagram of a portable multi-port solar charge system in an expanded position according to one aspect of the invention;

FIG. 9 illustrates several embodiments for incorporating a solar charge system as a part of a portable storage apparatus according to one aspect of the invention;

FIG. 10 illustrates a side perspective view of a portable storage apparatus incorporating a solar charge system for charging an electronic device according to one aspect of the invention;

FIG. 11 illustrates a front perspective view of a solar panel holder according to one aspect of the invention;

FIG. 12 illustrates a rear perspective view of a solar panel holder according to one aspect of the invention;

FIG. 13 illustrates a top perspective view of a solar energy repository having extended power receptacles according to one aspect of the invention;

FIG. 14 illustrates a top perspective view of a compact solar energy repository according to one aspect of the invention;

FIG. 15 illustrates a top perspective view of a compact planar solar energy repository according to one aspect of the invention; and

FIG. 16 illustrates a functional block diagram of an energy repository according to one aspect of the invention.

### DETAILED DESCRIPTION OF THE INVENTION

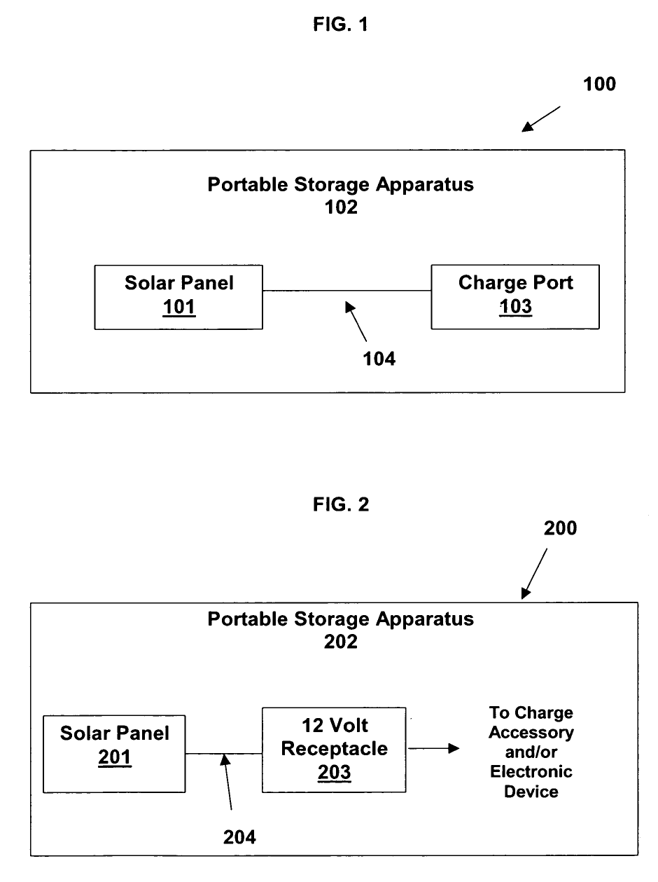

Advantageous embodiments of the invention are illustrated in FIGS. 1-16 and provide environmentally conscious alternatives for charging batteries associated with electronic devices. In one form, solar energy is converted into a direct current voltage and/or current for charging electronic devices such as cellular phones, personal digital assistants, personal computing devices, digital cameras, digital video recorders, music players, laptop computers or other portable electric devices such as cordless screw drivers, cordless drills, or other rechargeable cordless power tools or devices. Portable storage apparatuses for use in mobile environments are disclosed and include solar charge systems to actively charge rechargeable batteries associated with electronic devices stored within the a storage apparatus. A charge system includes a solar panel or solar photovoltaic module integrated as a part of the portable storage apparatus to actively convert solar energy to electrical energy sufficient to charge the electronic device stored within the portable storage apparatus. In this manner, a portable storage apparatus may be used in a mobile environment to actively charge electronic devices obviating the need to use conventional or terrestrial energy sources.

In a particularized form, a portable storage apparatus includes a backpack for storing articles and use within a mobile environment. The backpack includes at least one solar panel or photovoltaic module integrated as a part of an exterior surface of the backpack. Storage space is provided internal to the backpack for storing an electronic device and includes a universal twelve-volt charge port for receiving a charge accessory operably associated with coupling direct current energy to the electronic device to charge a battery associated with the electronic device. The portable storage apparatus allows for active charging of the electronic device as the backpack is used within a mobile environment providing efficient use of both the backpack and the solar charge system.

Solar panels and photovoltaic modules may be used interchangeably throughout the detailed description and should be viewed generally as solar energy converting devices operable to convert solar energy into electrical energy. As such, solar panels, solar modules, and photovoltaic modules may be used interchangeably throughout the description and should not be viewed in a limiting sense and may be operable to produce one or more levels of power. For example, a solar panel module may be used to produce several watts of power at several different voltage and current levels (i.e. 2.2 Watts at 7.6 volts and 290 milliamps, 2-12 Volt levels, 300 Watts, etc.) sufficient to charge an electronic device. Additionally, each solar panel or solar panel module may include at least two conductive elements (i.e. positive and negative reference terminals) for direct current power provided by using solar energy to an output port. As such, conductors or conductive elements are disclosed without showing each specific terminal and may be realized as multiple conductors or conductive elements, conductor pairs for coupling direct current, or other conductors as needed for coupling energy between components, output ports, receptacles, etc.

FIG. 1 illustrates a block diagram of a portable storage apparatus having an integrated solar charge system according to one aspect of the invention. Solar charge system, illustrated generally at 100, includes at least one solar panel 101 operable to receive solar energy and convert solar energy into a direct current voltage or current. Solar panel 101 may be integrated as a part of an exterior portion of portable storage apparatus 102 providing continuous access to solar energy in mobile environments. Solar panel 101 may include a rigid solar panel such as a fifty watt twelve-volt solar panel module manufactured by Astropower may be used. another embodiment, solar panel 101 may include a In flexible solar panel integrated as a portion of portable storage apparatus 100. For example, a flexible solar panel manufactured by Unisolar may be ˜integrated as a part of an outer surface of portable storage apparatus 100 and may be a thirty-two watt twelve-volt power sources. Flexible solar panels advantageously allow for increased durability and use of a portable storage apparatus 100 in a mobile environment and include flexible light-weight cells coupled to flexible stainless steel sheet of material. Several different types of solar energy panels may be used to output energy as needed and may be operable to output several different levels of energy (i.e. five watts, ten watts, 25 watts, 50 watts, etc.) sufficient to charge an electronic device.

Solar panel 101 is integrated as a part of an exterior portion of a portable storage apparatus 102 operable to store articles for use in a portability or mobile environment. Solar panel may be integrated as a part of an exterior surface depending on the type of apparatus and application of portable storage apparatus. For example, solar panel 101 may be integrated as a part of a fabric and sewn or bonded to a specific area, inset within a molded portion and held in place with a bonding or adhesive material or coupling mechanisms such as screws, nuts, etc. Charge port or port 103 is coupled to solar panel 101 via conductive element 104 operable to provide an electrical connection for charging an electric device coupled to charge port 103 (not expressly shown).

Though illustrated as a single solar panel, it should be understood that solar panel 101 may include several solar panels integrated as a part of storage apparatus 100 and as a part of solar charge system 101 and may include several combinations of flexible and/or rigid solar panels integrated as a part of portable storage apparatus 100 internal and/or external to portable storage apparatus 100. During use, solar charge system 100 receives and converts solar energy into direct current energy for charging a battery associated with an electronic device. For example, solar panel 101 may convert solar energy to provide a fifty-watt output and provides the converted energy to charge port 103 operable to coupled the converted solar energy to an electronic device such as a GPS unit, PDA, digital music player, cell phone, CD player, cassette player, digital camera, portable scanner or copier, or other electronic or electric power tools such as cordless drills, screwdrivers, saws, etc. For example, solar panel 100 may provide a minimum output sufficient to charge an electronic device. In another embodiment, a device specific charge circuit (not expressly shown) may include electronic components configured to convert the energy output from solar panel 100 to a specific level based on a charge specification of the electronic device. For example, the charge circuit may include one or more resistive elements configured to reduce the energy level to a level sufficient to charge the electronic device. Additionally, other devices such as current limiting devices such as fuses and blocking diodes may be provided to safely charge the electronic device without risking damage or depleting energy within the electronic device. For example, a blocking diode may be used to eliminate reverse current conditions that may deplete energy stored within a rechargeable battery and/or electronic device. A blocking diode may be provided between solar panel 101 and charge port 103 to obviate undesired reverse current conditions. In one embodiment, a device specific charge port may also be provided and may include one or more specific contact or conductive elements positioned to interface the electronic device to charge the electronic device. As such, storage apparatus 100 may include device specific configurations to accommodate charging a specific electronic device.

Solar charge system 100 is incorporated as a portion of portable storage apparatus 102 and includes solar panel 101 integrated as a part of storage apparatus 102 to provide an active system for charging an electronic device. Solar panel 101 integrated as a part of a storage apparatus 102 obviates the need to couple a solar panel accessory to an electronic device and provides for both charging and storage of the electronic device. For example, solar charge system 100 integrated as a part of storage apparatus 102 advantageously allows a user to be mobile obviating the need to set up non-mobile solar charge systems or use conventional or terrestrial energy sources to charge electronic devices. Additionally, through integrating solar panel 101 as a part of storage apparatus 102, undesired damage caused from jarring a solar panels that extend beyond a surface of storage apparatus 102 may be avoided adding to increased durability, use, and longevity of the solar charge system 100.

FIG. 2 illustrates a block diagram of a portable storage apparatus having a solar charge system incorporating a universal charge port according to one aspect of the invention. Solar charge system 200 includes a first solar panel 201 integrated as a part of portable storage apparatus 202. Solar charge system 200 includes a ˜universal twelve-volt charge port 203 coupled to solar panel 201 via conductor 204 and operable to couple a universal twelve-volt plug and charge adapter or accessory to port 203. For example, some electronic devices may be charged using a universal twelve-volt charge adapter. As such, solar charge system 200 including universal twelve-volt charge port 201 advantageously allows for use of conventional charge accessories that convert and/or couple direct current power to charge electronic devices. In this manner, portable storage apparatus 202 may not require additional device specific charge circuitry and may allow for several different types of charge accessories for specific electronic devices to be used in association with portable storage apparatus 200 allowing for several different electronic devices to be charged using converted solar energy provided by solar charge system 201.

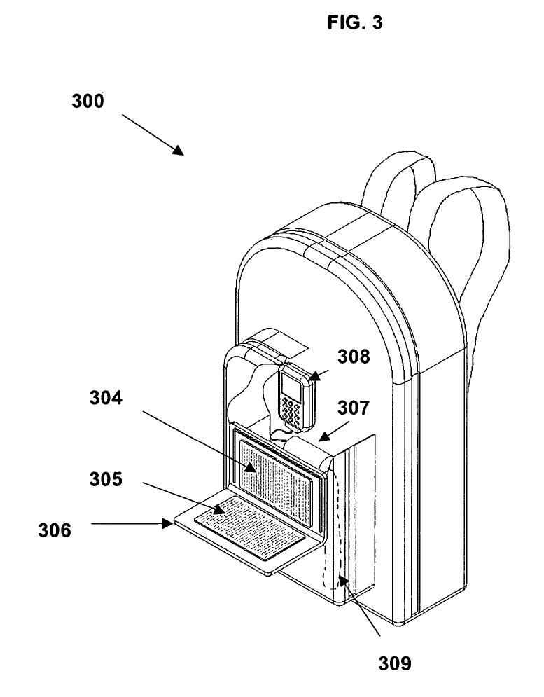

FIG. 3 illustrates a portable storage apparatus incorporating a solar charge system for charging an electronic device according to one aspect of the invention. A portable storage apparatus, illustrated as backpack 300, includes a positional solar panel holder 306 integrated as a part of an exterior portion of backpack 300 and securely holding a first solar panel 304 and a second solar panel 305.

For example, solar panel holder 306 may include a fabric material substantially similar to backpack 300 and operable hold solar panels 304 and 305 in place. For example, solar panel holder 306 may include cavity (not expressly show) as a part of solar panel holder 306 and a durable optically transparent material stitched over each solar panel to hold each solar panel in place. Additionally, padding material may be provided as a backing behind each solar panel holder to reduce mechanical shock that may occur during use. As such, through integrating each solar panel as a part of an exterior portion of backpack 300, undesired damage that may occur though coupling solar panels to external an surface of a backpack or storage apparatus may be reduced.

Positional solar panel holder 303 may be lowered or raised depending on the desired use of backpack 300. For example, when positional solar panel holder 306 is lowered first and second solar panels 304 and 305 are used to charge an electronic device. However, when a user does not desire to use first and second solar panels 304 and 305, Positional solar panel may be raised and coupled to a portion of backpack 300 using coupling element 310. Additionally, a third solar panel may be integrated as a part of an opposing side of solar panel holder 306 (not expressly shown) and operable to convert solar energy when solar panel holder 306 is in a raised position. Additionally, one or more coupling mechanisms may be used to secure positional solar panel holder 306 using coupling element 306. For example, coupling element 310 may include a zipper, hook and loop material, snaps, buttons, clasps, or other fastening mechanisms for securing positional solar panel holder 303 in a closed position.

Backpack 300 further includes a charge port 307 electrically coupled to solar panels 304 and 305 to facilitate charging an electronic device 308. Charge port 307 is coupled to an interior portion of backpack 300 allowing for storage of electronic device 308 within backpack 300 while allowing a user to charge electronic device 308 while backpack 300 is used in mobile environments. In one embodiment, charge port 307 (or an additional charge port) may be externally accessed. For example, charge port 307 may be located along a side portion of backpack 300 and accessible external to backpack 300 allowing a user to charge electronic device 308 without storing electronic device 308 within backpack 300. For example, an electronic device, such as a cellular telephone, may coupled to an external accessible charge port allowing a user to use the cellular telephone while the cellular telephone receives a charge from solar panels 304 and 305.

In one embodiment, charge port 307 may include a universal charge port for coupling a charge accessory to electronic device 308. For example, charge port 307 may be configured as a universal twelve-volt port for coupling a twelve-volt charge accessory operable to receive energy from a direct current energy source and convert the energy if needed to a level sufficient to charge electronic device 308. In this manner, several different types of charge accessories may be coupled to the universal twelve-volt charge port for charging electronic device 308.

In one embodiment, backpack 300 may include materials to protect environmental sensitive components of backpack 300. For example, one or more components may be sealed or laminated in a flexible material to provide sustained use adverse climate conditions. For example, liquid or water-resisting materials maybe used to reduce the risk of device degradation and potential risks associated with electrical shock that may result from using backpack 300 in precipitating environments. For example, solar panels 304, 305, conductor 309, and electrical port 307 may be sealed with one or more types of sealing materials such as weather resistant polymers, silica or plastic sealants, shrink wrap materials, or other materials to isolate environmentally sensitive components.

In another embodiment, backpack 300 may include a solar panel cover (not expressly shown) of a material that substantially matches the color of backpack 300 to conceal the solar panels from plain view. For example, a UV transmitting materials that allow select frequencies of light to be transmitted through the material to a solar panel may be used while concealing the solar panel from plain view. In this manner, select solar panels may be concealed using material substantially the same color as the main body of backpack 300. However, in other embodiments combinations of colors and material types may be used and integrated as a part of backpack to optimize performance, desired styling, and efficiency of backpack 300 as needed. Additionally, a UV transmitting material may be operable to allow incident light to be transmitted though the material and may further be operable to capture reflected light that may reflect off a portion of a solar panel. For example, a portion of the incident light may be reflected off of the surface of the solar panel surface and again reflected off of the back surface of the UV transmitting material. As such, solar energy that may not normally be captured may be reflected multiple times to the surface of each solar panel thereby increasing the efficiency solar energy conversion. In one embodiment, the UV transmitting material may include a backing material operable to help with reflecting solar energy back to the surface of the solar panel. For example, a thin film of reflective material may be coupled to the UV transmitting material and may allow for transmission of light in one direction (i.e. from the solar source) to the solar panel and reflect solar energy reflected from the solar panel back to the surface of the solar panel.

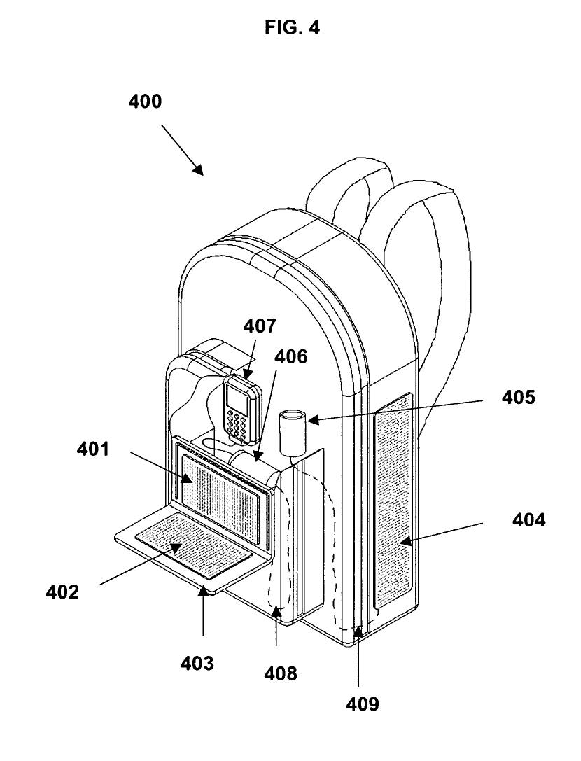

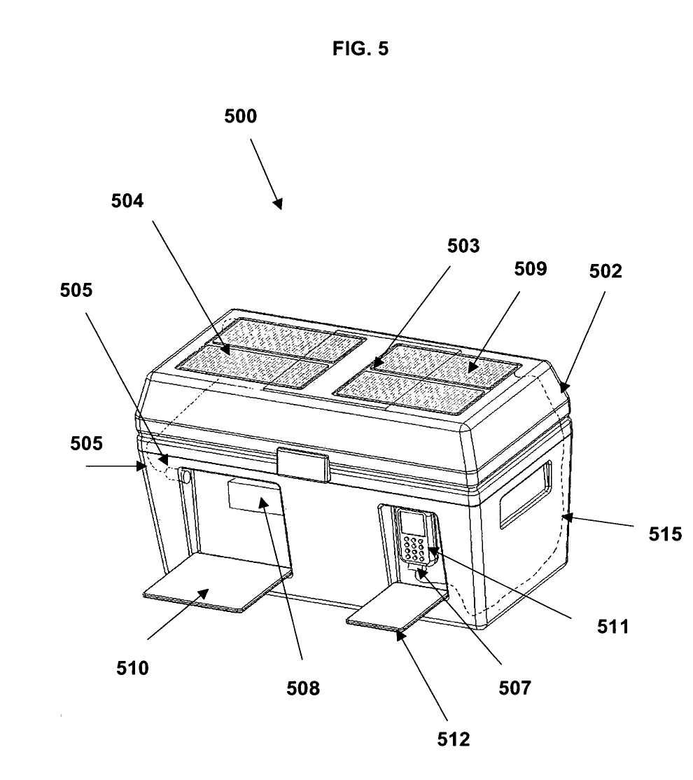

FIG. 4 illustrates a portable storage apparatus incorporating plural solar charge panels and charge ports according to one aspect of the invention. A portable storage apparatus, illustrated generally as backpack 400, includes first and second solar panels 401 and 402 integrated as a part of a positional panel 403 coupled to an exterior portion of backpack 400. Backpack 400 further includes a third solar panel 404 is integrated as an exterior portion of backpack 400 and may include a flexible solar panel. First and second solar panels 401 and 402 are coupled to a first charge port 406 via conductor 408 for providing a charge to charge electronic device 407. Third solar panel 404 is coupled to second charge port 405 via second conductor 409. Second charge port 405 is operable as a universal twelve-volt charge port for charging an electronic device using a charge accessory (not expressly shown).

During use, solar energy is converted from each solar panel and coupled to an electronic device needing charging. Energy is converted by each solar panel and coupled to a respective charge port and may be used in a mobile setting obviating the need for remaining in a fixed location to charge an electronic device. Through providing third solar panel 404 as a flexible solar panel to a side portion of backpack 400, backpack 400 may be expanded, collapsed, and/or in a traditional manner. Additionally, through providing multiple solar panels and associated charge ports, several electronic devices may be charged using backpack 400 in a mobile setting.

FIG. 5 illustrates a thermal storage apparatus incorporating a solar charge system according to one aspect of the invention. A thermal storage apparatus, illustrated generally as thermal cooler 500, includes a first solar panel 504 and second solar panel 509 integrated as a part of top portion or lid 502 of thermal cooler 500. For example, lid 502 may include a plastic mold recess operable to house each solar panel and integrate each solar panel as a portion of lid 502. Each solar panel may be flush with the surface of the lid, or recessed below the top surface of the lid in a non obtrusive manner. A removable and/or positional solar panel access panel 503 is coupled to lid 502 and provides access to solar panels 504 and 509. Thermal cooler 500 further includes a first charge port 505 coupled to a first side portion 506 of thermal cooler 500 and accessible via access panel 510. First charge port 505 may include a universal coupling port such as a universal port operable to allow coupling of a charge accessory for charging an electronic device (not expressly show). Thermal cooler 500 further includes a second charge port 507 having electrical contacts and coupling mechanisms operable to securely couple electronic devices having a specific contact specifications. Additionally, thermal cooler 500 may include a charge circuit (not expressly shown) between solar panels 504, 509 and charge ports 505 and 507. For example, a charge circuit may be operable to provide a specific level of energy converted by solar panel 504 and/or 509 to each charge port based on an electronic device's charge specification. For example, an electronic device may require a minimum charge of one hundred milliamps to sufficiently to charge the electronic device. As such, thermal cooler 500 may be configured to charge specific electronic devices having minimum charge specifications.

Thermal cooler 500 further includes charge port 507 and access panel 513 for storing an electronic device. For example, thermal cooler 500 may include a recess 512 and access panel 513 and may be used to store and to protect electronic device 511 from undesired bumping or jarring.

During operation, solar panel access panel 503 may be slid or removed to expose solar panel 504 and 509 to initiate conversion of solar energy into a direct current energy. For example, solar panel access panel 503 may be integrated as a part of lid 502 and coupled to a slide track (not expressly shown) to allow access to solar panels 504 and 509 when needed while providing protection of solar panels 504 and 509 when not being used.

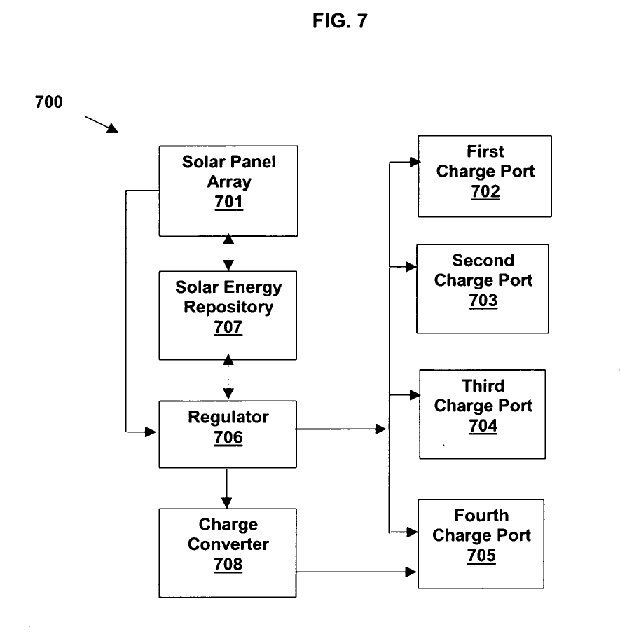

Solar energy incident to solar panel 504 and/or 509 is converted to a direct current energy and coupled to charge port 504 via conductor 501 and to charge port 507 via conductor 515. In one embodiment, solar panel 504 may be used exclusively with charge port 505 to charge an electronic device and solar panel 509 may be used exclusively with charge port 507 to charge an electronic device. As such, solar panels 504 and 509 may be independently used to charge an electronic device using an associated charge port. However, in other embodiments, solar panels 504 and 509 may collectively convert solar energy and may be distributed to between each charge port as needed to charge an electronic device. FIG. 7 described below describes one embodiment of solar charge system operable to distribute energy between charge ports and may be incorporated as a part of thermal cooler 500.

In one embodiment, solar panel access panel 503 may be made of a material that allows transmission of solar energy to solar panels 504 and 509 while covering or protecting solar panels 504 and 509. For example, user may desire to set objects (i.e. drinks, cans, food, or other articles) on the top of thermal cooler 500. As such, through providing a material that allows for protection of solar panels 504 and 509 and further allows for transmission of solar energy to solar panels 504 and 509, cooler 500 may be used in a traditional manner without requiring special consideration.

In one embodiment, thermal cooler 500 may include a solar energy repository 508 operable to store converted 20 solar energy. Solar energy repository 508 may be coupled to first solar panel 504 and/or second solar panel 509 and may store converted solar energy. For example, a user may use an electronic device in a mobile setting away from thermal cooler 500. As such, thermal cooler 500 may store converted energy within solar energy repository 508 and upon a user returning to thermal cooler 500, the user may couple an electronic device requiring charging to port 505 or 507 and energy stored within solar energy repository 508 may be used to charge the electronic device. Additionally, energy being converted from solar panels 504 and 509 may also be used with repository 508 to charge the electronic device. In this manner, a user may charge an electronic device using stored energy and actively converted solar energy thereby reducing the amount of time needed to charge the electronic device.

Thermal cooler 500 may be provided in an ‘active on’ mode of operation wherein solar energy is converted until repository 508 and/or an electronic device is fully charged and solar energy may not be converted unless a deficiency of energy exists within one and/or the other. For example, a detection circuit or blocking diode (not expressly shown) may be used to determine a charge level of the electronic device and or repository 508. As a battery for an electronic device is fully charged (i.e. minimum current is drawn to charge the battery), a detection circuit or blocking diode may isolate the electronic device and/or charge repository from solar panels 504 and 509 to reduce or minimize solar energy conversion and transverse currents that may deplete energy stored within the electronic device of repository 508. For example, as the charge level of the rechargeable battery of the electronic device exceeds the charge level of repository 508, current may be reversed do a higher relative charge level of the electronic device's battery relative to repository 508. Through providing a blocking diode or detection circuit, the current path between each battery may be limited based on the amount and direction of current passing between the electronic device and the charge system. In a further example, a blocking diode or detection circuit may be used to maintain a charge direction when a solar panel is not exposed to solar energy and is not converting energy sufficient to maintain a current output to charge the electronic device. Although some conventional solar panels or solar charge modules may include bypass diodes integrated as a part of the solar panel or solar module, it may be necessary to include additional detection circuits or blocking diodes to minimize undesired transverse or reverse current situations that may deplete energy stored within the electronic device. In this manner, solar energy may only be converted if used to charge an electronic device or charge repository.

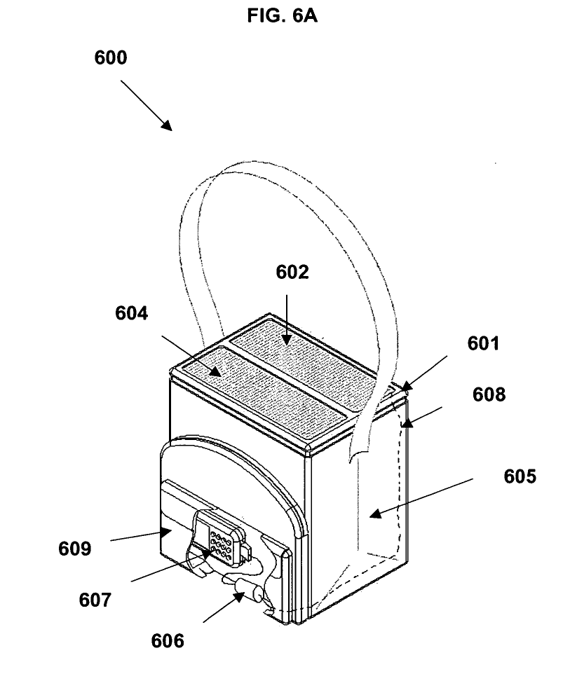

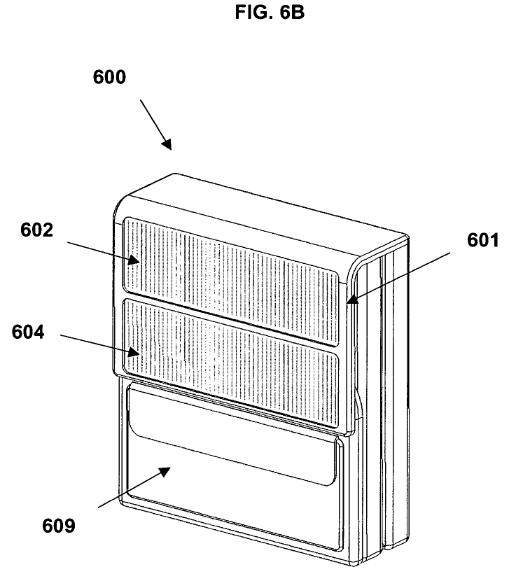

FIG. 6A illustrates a collapsible solar storage apparatus in an expanded position incorporating a solar charge system according to one aspect of the invention. Collapsible solar storage apparatus, illustrated generally as collapsible cooler 600, includes a first solar panel p02 and second solar panel 604 integrated as a part an upper portion 601 of collapsible cooler 600. Each solar panel may be integrated through providing a cavity or recess (not expressly shown) for housing each solar panel in a non-obtrusive manner. For example, upper portion 601 may include a cavity made of substantially the same materials as collapsible cooler 600 to integrate each solar panel as a portion of upper portion 601. Collapsible cooler 600 further includes a cooler cavity 605 for storing articles, and maintaining a thermal state (i.e. hot, warm, cold, etc.). Collapsible cooler 600 includes a charge port 606 operable to couple electronic device 607 stored within side storage compartment 609. For example, a user may couple a cellular phone to charge port 606 to charge the cellular phone's rechargeable battery using a direct current energy provided by solar panels 602 and 604 via conductor 608. Solar panels 602 and 604 may include rigid or flexible solar panels and may be sized to provide a desired solar energy conversion rate sufficient to charge electronic device 607.

FIG. 6B illustrates collapsible cooler 600 in a collapsed or compacted position. Collapsible cooler 600 may be collapsed or compacted such that solar panels 602 and 604 remain exposed to solar energy to convert energy as needed. Additionally, upper portion 601 is folded in a downward position and extends to the top portion of side storage compartment 609 and allows for access to storage compartment 609 operable to house electronic device 607 and charge port 606. In this manner, electronic device 607 may be accessed and charged as needed when cooler 600 is placed in either an expanded or collapsed position.

FIG. 7 illustrates a block diagram of a solar charge system according to one aspect of the invention. Solar charge system, illustrated generally at 700, includes a solar panel array 701 and a first charge port 702, a second charge port 703, a third charge port 704 and a fourth charge port 705. Each charge port may include a blocking diode operable to restrict current from being reversed to regulator 706 and a fuse or current limiting element operable to limit the amount of current coupled to each port. A solar energy repository 707 is coupled between regulator 706 and solar panel array 701 and is operable to store energy converted by solar panel array 701. A charge converter 708 is coupled to regulator 706 and fourth charge port 705 and provides a specific charge level to fourth charge port 705 as needed. Regulator 706 is coupled to each charge port and is operable as a solar energy regulator and distribution module operable to provide direct current energy for charging plural electronic devices. Regulator 706 may include a current limiting element for each output port and may also include blocking diodes for eliminating reverse current conditions that may be present from time to time as each electronic device is charged.

During use, system 700 converts solar energy to direct current energy using solar panel array 701 which may include several solar panels or modules operable to convert solar energy to a direct current energy. Each solar panel or module associated with solar panel array may be integrated as a part of a portable storage apparatus (not expressly shown) for actively converting solar energy in a mobile environment. Solar panel array 701 converts solar energy to direct current energy and couples the converted energy to solar energy repository 707 and regulator 706.

Regulator 706 may be used to combine the outputs of several solar panels or modules and couple the converted energy to each port as needed. For example, each port may be configured to output fifty watts of power to charge an electronic device. As such, regulator 706 may couple fifty watts of power to each port. Similarly, each port may include different specifications for charging an electronic device. For example, first charge port may be operable to output 30 watts at 500 millivolts, second output port may be operable to output 40 watts at six volts, and third output port may be operable to output 50 watts at twelve volts. As such, regulator 706 ensures that each output level is maintained through coupling energy to each charge port. For example, regulator 706 may include a voltage and/or current divider operable to facilitate outputting an associated output level to each port using energy converted by solar panel array 701.

In one embodiment, regulator 706 may include a detection circuit to detect when an electronic device is coupled to each port and distribute energy between each active port to ensure a minimum output level is provided for each port. A detection circuit may include a feedback circuit operable to detect when the impendence of each port is altered couple or remove an output accordingly. Additionally, regulator 706 may also distribute excess energy to solar energy repository 707 operable to store converted solar energy. In one embodiment, when an electronic device is not coupled to a port or has been sufficiently charged, regulator 706 may divert converted energy to solar energy repository 707 to store energy as needed.

Regulator 706 may also be preprogrammed and/or reprogrammed to output specific power levels to each charge port. For example, regulator 706 may include a processor and digitally encoded control circuit logic (not expressly shown) operable to access a memory device such as a ROM, EEPROM, Flash memory, etc. operable to provide a specification for each charge port. Regulator 706 may then use the specification and an associated programmable voltage divider to provide a desired output to a specific charge port. As such, specifications for each port may be provided within a programmable memory and updated through reprogramming memory to provide a new specification.

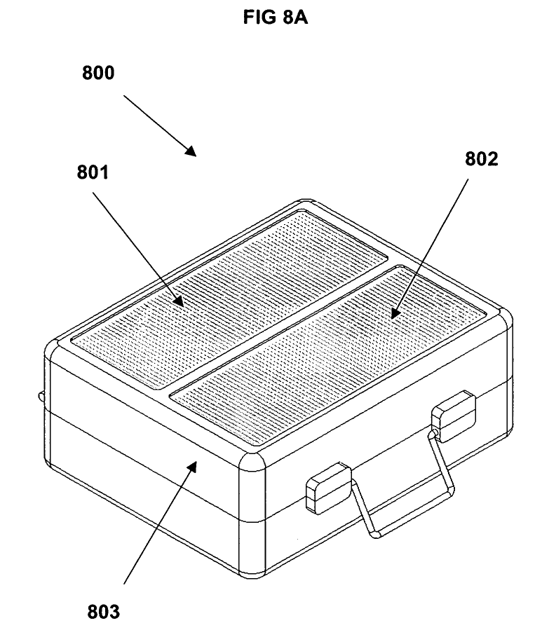

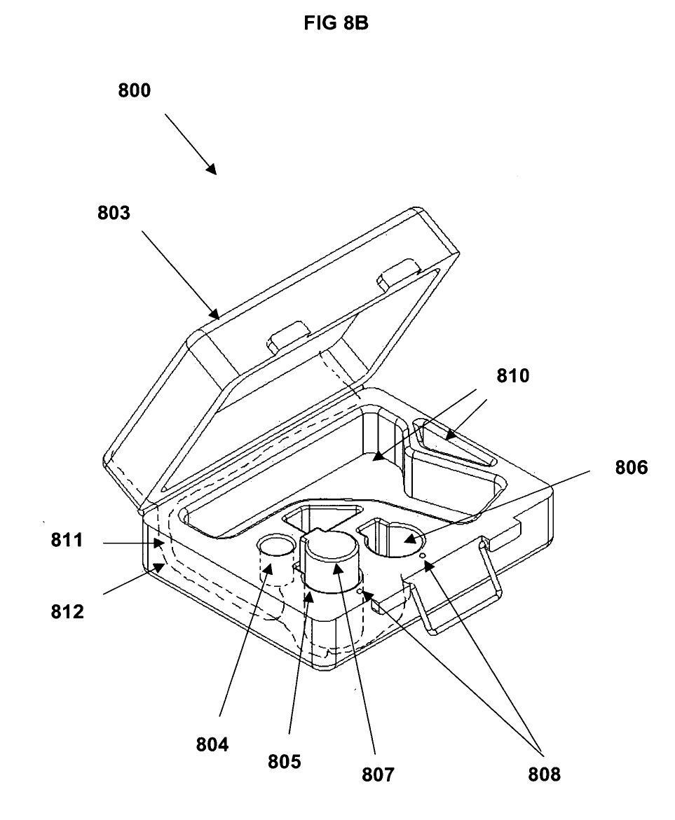

FIG. 8A illustrates a diagram of a portable multi-port solar charge system in a closed position according to one aspect of the invention. A portable multi-port solar charge system, illustrated generally as a storage apparatus 800, includes a first solar panel module 801 and second solar panel module 802 integrated as a portion of a lid 803. Each solar panel module may include a rigid solar panel module or flexible solar panel module and may be operable to output one or more levels of converted energy. For example, each panel may be configured to output up to fifty watts of power. Each solar panel is integrated as a part of lid 803 through providing a recess or cavity as a part of lid 803. For example, lid 803 may include a molded recess to allow for holding each solar panel in a non-obtrusive manner. Each solar panel may be held using mounting mechanism (not expressly shown) such as brackets, screws and nuts, or adhesive materials operable to mount a solar panel to storage apparatus 800. Additionally, each panel may include a protective material coupled to a back portion of each solar panel to protect each solar panel from the rough handling and the elements. For example, each solar panel may include a shock absorbing material or cushion material coupled to the back portion in addition to a plastic material or polymer for protection from the elements.

FIG. 8B illustrates a diagram of a portable multiport storage apparatus in an expanded or open position and includes a storage areas or cavities 810 for storing an electronic device such as a cordless drill or other accessories and a first charge port 804 configured as a universal twelve-volt charge port, second and third charge ports 805 and 806 operable to receive a rechargeable battery. Each charge port may include a status indicators 808 to indicate a charge status of an electronic device or battery.

Each charge port is coupled to first and second solar panel module 801 and 802 via first and second conductors 811 and 812. Each charge port may be directly coupled to each solar panel array to obtain a charge directly from each solar panel module. For example, second charge port 805 may be Connected in parallel with third charge port 806 and further coupled to first solar panel module 801. Additionally, second solar panel module 802 may be directly coupled to universal twelve volt charge port 804 for charging an electronic device. However, other embodiments may include incorporating solar charge system 700 of FIG. 7 for charging an electronic device or battery.

During use, a user may couple an electronic device to first charge port 804 and may further plug battery 807 into second charge port 805 for charging. Lid 803 may be rotated to an optimum position to facilitate charging an electronic device or battery. For example, lid 803 may be rotated and fixed to optimize solar energy incident to lid 803 and may include a positional element 813 to fix the angle of lid 803 relative to incident solar energy. Status indicators 808 may also be used in association with positioning lid 803 and may illuminate brighter or dimmer based on the amount of energy being converted by first and second solar panel modules 802 and 803. Each electronic device or battery is charged using converted solar energy and upon being charged completely, ‘status indicator may detect the level of current being drawn by the electronic device or battery and illuminate green to indicate that a full charge has been achieved. Additionally, each charge port may include current limiting elements and blocking diodes to protect from excessive currents or reverse current conditions.

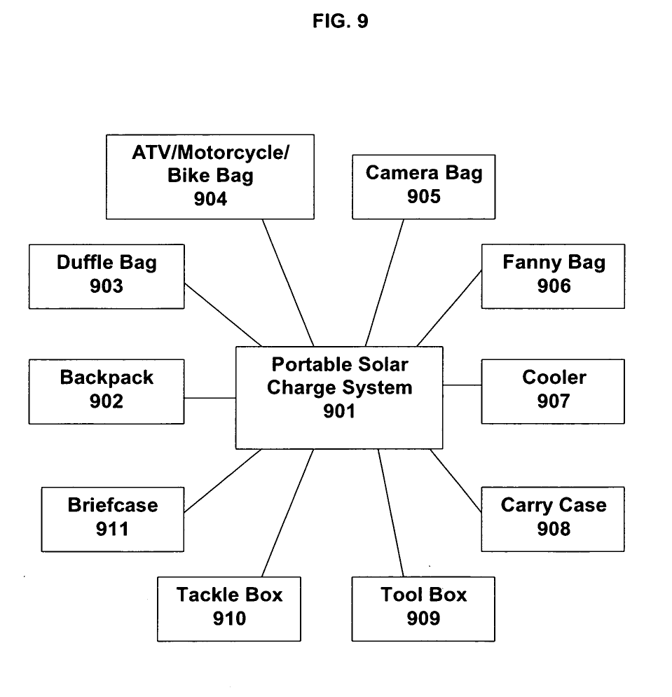

FIG. 9 illustrates several embodiments for incorporating a solar charge system as a part of a portable storage apparatus according to one aspect of the invention. Portable solar charge system 901 may be integrated as a part of a backpack 902, a duffle bag 903, a saddle bag 904 for a motorcycle, motorized bike, or all terrain vehicle (ATV), a camera bag 905, a ‘fanny bag’ 906 operable to be coupled around a person's waist, a cooler 907, a carry case 908 such as a computer bag for storing a laptop computer or for storing power tools, a toolbox 909, or a tackle box 910. Additionally, several other types of portable storage apparatuses may take advantage of integrating a portable solar charge system 901 for use in a mobile environment. As such, portable solar charge system 901 may be integrated as a portion of a portable storage apparatus for charging an electronic device stored within the portable storage apparatus. Solar energy may be converted to direct current energy allowing for a user to charge an electronic device in a mobile environment when terrestrial and/or conventional energy sources may not be available.

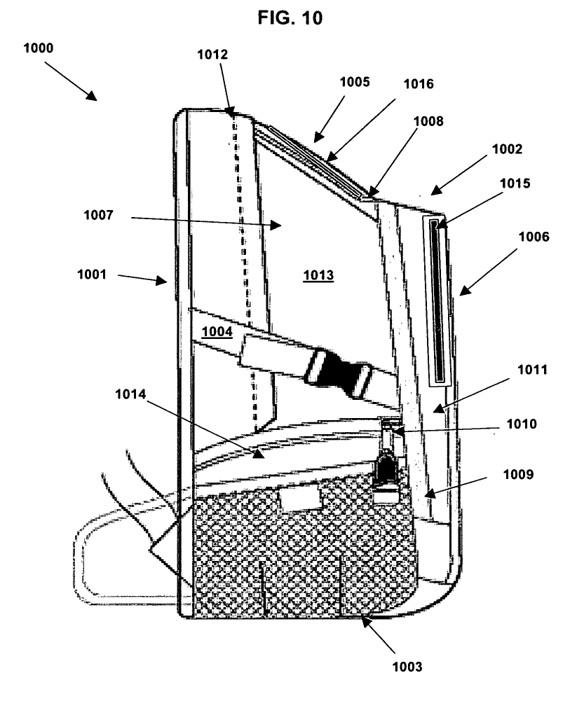

FIG. 10 illustrates a side perspective view of a portable storage apparatus incorporating a solar charge system for charging an electronic device according to one aspect of the invention. A portable storage apparatus, illustrated generally as backpack 1000, having a front portion 1001, a rear portion 1002 and a side portion 1007 including an adjustable strap 1004 for adjusting the overall width of backpack 1000. Side portion 1007 further includes an exterior side pocket 1003 for storing contents and providing a user easy access and storage of articles. Backpack 1000 further includes a first zipper 1009 operable to provide access to a rear storage compartment 1011, a second zipper 1012 operable to provide access to a main storage compartment 1013, and a third zipper 1010 operable to provide access to an interior side storage compartment 1014.

Backpack 1000 further includes a rear solar panel holder 1006 integrated as a part of an exterior surface of rear portion 1002 and operable to house a rear solar panel 1015. Top portion 1005 includes a top solar panel holder 1008 integrated as a part of an exterior surface of top portion 1005 and operable to house a top solar panel 1016. Rear solar panel 1015 and/or top solar panel 1016 may be provided as a rigid or flexible solar panel. Additionally, rear solar panel 1015 and top solar panel 1016 are integrated as a part of an exterior surface of rear portion 1002 and top portion 1005 to help minimize or reduce protruding or extending away from backpack 1000 to reduce accidentally breaking or damaging rear solar panel 1015 and top solar panel 1016 when backpack 1000 is used.

Rear solar panel 1015 may be accessed using first zipper 1009 to open rear storage compartment 1011. Upon opening first zipper 1009, rear solar panel holder 1006 may be accessed from an interior portion of rear storage compartment 1011 allowing a user to remove rear solar panel 1015 from rear solar panel holder 1006 as needed. Similarly, top solar panel 1016 may also be accessed using second zipper 1012 to open main storage compartment 1013 to provide access to top solar panel holder 1008 allowing a user to remove top solar panel 1016 as needed. In some embodiments, rear solar panel 1015 and top solar panel 1016 either, alone or in combination, may include a flexible or rigid solar panel and may be removable or non-removable. For example, rear solar panel 1015 may be include a rigid solar panel which may be removed from rear solar panel holder 1006 and top solar panel 1016 may include a flexible solar panel that may not be removed from top solar panel holder 1008.

During use, a user may store an electronic device (not expressly shown) within backpack 1000. A receptacle or charge port (not expressly shown) provided in association with top solar panel 1016 and/or rear solar panel 1015 may be coupled to the electronic device. In one embodiment, rear solar panel 1015 and top solar panel 1016 may both provide energy to a single receptacle or charge port. However other embodiments may include providing separate charge ports, and/or multiple charge ports for top solar panel 1016 and rear solar panel 1015.

In one embodiment, a user may remove rear solar panel 1015 including a receptacle or charge port from rear solar panel holder 1006 as needed. For example, if rear solar panel 1015 becomes damaged or is faulty, a user may remove rear solar panel 1015 from rear solar panel holder 1006 through accessing rear storage compartment 1011. In this manner, a user need not purchase a new backpack if rear solar panel 1015 becomes faulty.

In another embodiment, rear solar panel 1015 may be provided with a specific type of charge port, receptacle, plug, etc. (not expressly shown) for a specific electronic device. As such, rear solar panel 1015 may be removed and replaced as needed to accommodate a variety of difference types of electronic devices having specific charge ports for charging.

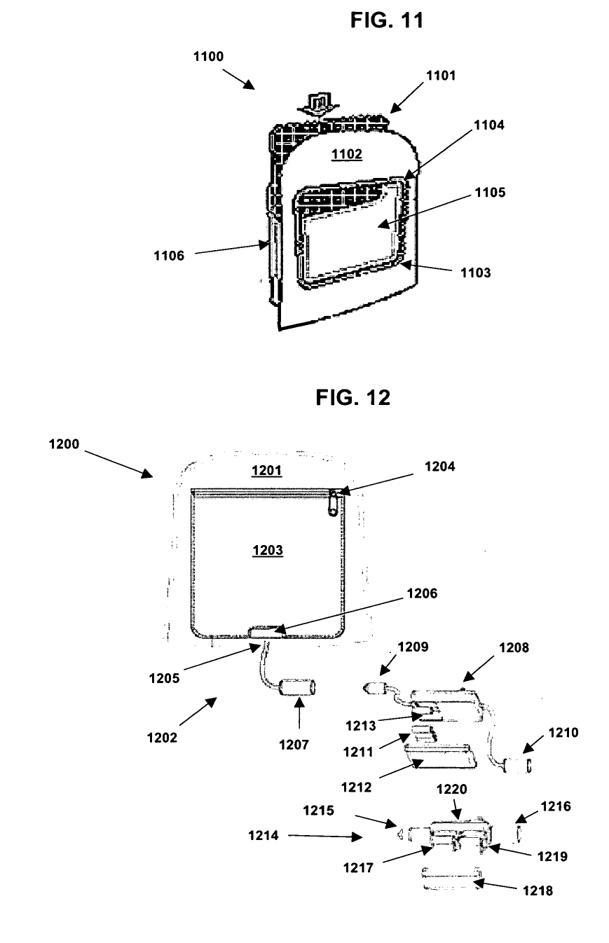

FIG. 11 illustrates a front perspective view of a solar panel holder according to one aspect of the invention. A solar panel holder, illustrated generally at 1100, includes an exterior surface 1102 and an interior cavity 1106 sized to house a solar panel 1101 and to integrate solar panel 1101 as a portion of exterior surface 1102. Solar panel holder 1100 may be used either alone or in combination with various types of and/or elements of various portable storage apparatuses including, but not limited to, portable storage apparatuses illustrated in FIG. 9.

Exterior surface 1102 of solar panel holder 1100 includes an aperture 1105 having a retainer 1104 formed to cover a portion of solar panel 1101 and operable to expose solar panel 1101 to light when placed within solar panel holder 1100. Retainer 1104 is integrated as a part of exterior surface 1102 and may be made of the same material as exterior surface 1102 or other materials as needed. Retainer 1104 positions and/or aligns solar panel 1101 relative to aperture 1105 and along an interior of solar panel holder 1100 maintaining a substantially flat or planar surface thereby reducing protrusion or extension of solar panel 1101 beyond exterior surface 1102 to reduce damage that may be caused to solar panel 1101 during use. Cavity 1106 may be provided with a width, height and depth to house a conventional solar panel. For example, a conventional solar panel may include a size of six and three-fourths of an inch for a height and width. Various other sized solar panels may also be used. Additionally, solar panel holder 1100 may include various types and combinations of material such as padded materials, waterproofing materials, cloth materials, leathers, canvas, etc.

FIG. 12 illustrates a rear perspective view of a solar panel holder according to one aspect of the invention. A solar panel holder, illustrated generally at 1200, includes an interior surface 1201 and a solar panel holder cavity 1203 sized to house a solar panel (not expressly shown). Solar panel holder 1200 may be used either alone or in combination with various types of and/or elements of various portable storage apparatuses including, but not limited to, portable storage apparatuses illustrated in FIG. 9.

Solar panel holder 1200 further includes an access slot or zipper 1204 operable to provide access to a solar panel housed within solar panel holder cavity 1203. Solar panel holder 1200 further includes a solar panel charge interface 1206 which may provide an electrical interface for one or more types of connectors. For example, solar panel holder 1200 may be used in association with a twelve-volt (12-V) charger and may include solar panel charge interface 1206 having a conductor 1205 coupled to solar panel charge interface 1206 and coupling a universal 12-V female charge receptacle 1207 operable to couple converted solar energy to an electronic device or charger (not expressly shown). Solar panel charge interface 1206 having a universal 12-V female charge interface 1207 may be coupled to various types of electronic devices, chargers, batteries, etc. operable to use energy provided by a solar panel. In another embodiment, charge interface 1206 may include various other connector types that may be designed for specific electronic devices.

In another embodiment, one or more types of solar energy repositories may be coupled to universal 12-V female charge receptacle 1207. For example, a first solar energy repository 1208 may be coupled to universal 12-V female charge receptacle 1207 using a universal 12-V male charge plug 1209 to store converted solar energy within rechargeable batteries 1211. First solar energy repository 1208 includes a rechargeable battery holder 1213 for holding rechargeable batteries 1211 and providing electrical contacts for conducting energy to charge rechargeable batteries 1211. Rechargeable batteries 1211 may include lithium-ion, nickel-metal hydride, or other based batteries and may be provided in various sizes, including, but not limited to, AA, AAA, D, C, 9-Volt, or various other battery sizes and shapes including various camera batteries, cellular phone batteries, other portable electronic batteries sources and the like. As such, various sizes or shapes of rechargeable batteries may be charged and rechargeable battery holder 1213 may be sized to accommodate various types and sizes of batteries as needed. Additionally, various combinations and number of batteries may charged by first solar energy repository 1208. For example, rechargeable battery holder 1213 may be sized to charge two batteries, four batteries, six batteries, eight batteries, etc. and may include various sizes such as four ‘AAA’ batteries and two ‘AA’ batteries. Other combinations may also be employed.

First solar energy repository 1208 further includes a battery holder cover 1212 which may be removeably coupled to first solar energy repository 1208 for providing access to rechargeable batteries 1211. First solar energy repository 1208 further includes an universal 12-V female receptacle extension 1210 operable to connect an electronic device, charger, etc. to energy first solar energy repository 1208.

In another embodiment, a second solar energy repository 1214 may be coupled to universal 12-V female charge receptacle 1216 to charge rechargeable batteries 1217. Second solar energy repository 1214 includes a universal 12-V male charge plug 1215 coupled to housing 1220 and a universal 12-V female charge receptacle 1216 coupled to housing 1220. Second solar energy repository 1214 is provided as a compact repository operable to charge rechargeable batteries 1217 when placed within rechargeable battery holder 1219. A battery cover 1218 is removeably coupled to housing 1220 and provides access to rechargeable batteries 1217.

During operation, a user may couple either first solar energy repository 1208 (or second solar energy repository 1214) to universal 12-V female receptacle 1207 of solar panel holder 1200 and charge rechargeable batteries 1211 using solar energy converted from a solar panel housed within solar panel holder 1200. Electronics for regulating charging of each battery are provided within first solar energy repository 1208 and during periods of energy conversion, first solar energy repository 1208 provides sufficient energy to charge batteries 1211.

First solar energy repository 1208 may also be used to solely charge rechargeable batteries 1211 or may be used to provide energy to an electronic device coupled to universal 12-V female plug extension 1210. For example, first solar energy repository 1208 may detect when an electronic device is coupled to universal 12-V female plug extension 1210 and use converted energy to solely power the electronic device. In another embodiment, first solar energy repository 1208 may be operable to provide both converted solar energy provided from a solar panel within solar panel holder 1200 and, in addition to providing converted energy, couple energy stored within first solar battery repository 1208 to provide sufficient energy to power an electronic device. For example, energy stored within rechargeable batteries 1211 may be provided in combination with actively converted solar energy to provide sufficient power to power an electronic device. As such, first solar energy repository 1208 may include a voltage regulator operable to maintain power output by first solar energy repository 1208 when used in association with a solar panel and/or a solar energy converter.

In one embodiment, first solar energy repository 1208 may store energy within rechargeable batteries 1211 sufficient to power an electronic device when solar power is not be available (i.e. due to a damaged solar panel, dark environments, indoors, etc.). For example, a user may be indoors and couple an electronic device to first solar energy repository 1208 and first solar energy repository 1208 may provide energy using rechargeable batteries 1211 to provide power to an electronic device.

In another embodiment, a user may remove rechargeable batteries 1211 from first solar energy repository 1208 and use one or more rechargeable batteries 1211 within an electronic device operable to use rechargeable batteries 1211. Additionally, a user may continue to couple a second electronic device to first solar energy repository 1208 and provide solar energy and/or energy stored within one ore more rechargeable batteries 1211 remaining within rechargeable battery holder 1213. In this manner, a user may continue to use solar and/or stored energy to power a second electronic device while utilizing one or more batteries to power a first electronic device. For example, a user may use one or more rechargeable batteries 1114 to power a digital camera while first solar energy repository 1208 may be used to provide power to a cellular telephone using universal 12-V female receptacle 1210. Additionally, one or more rechargeable batteries may remain within rechargeable battery holder 1213 and may be used to provide the cellular phone as needed.

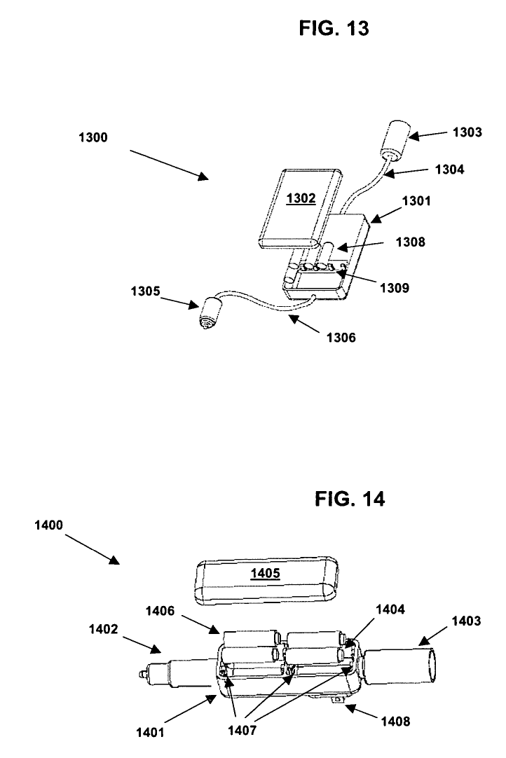

FIG. 13 illustrates a top perspective view of a solar energy repository having extended power receptacles according to one aspect of the invention. A solar energy repository, illustrated generally at 1300, includes a housing 1301 to store electronics for charging rechargeable batteries 1308 and coupling converted solar energy to an electronic device (not expressly shown) using universal 12-V female receptacle 1303 and universal male 12-V male plug 1305. Solar energy repository 1300 includes a first extension cable 1306 coupled to universal 12-V male plug 1305 and a second extension cable 1304 coupled to universal 12-V female receptacle 1303. Rechargeable batteries 1308 are housed within rechargeable battery holder 1307 including contacts 1309 for charging rechargeable batteries 1308. Rechargeable battery holder cover 1302 is removeably coupled to housing 1301 and provides access rechargeable batteries 1308.

During use, a user may couple solar energy repository 1300 to a solar energy converter or other power source operable to receive universal 12-V male plug 1305 and provide power to solar energy repository 1300 sufficient to charge rechargeable batteries 1308. For example, solar energy may be converted using types of solar energy conversion devices including, but not limited to, one or more portable storage apparatuses illustrated in FIG. 9. Solar energy may be converted and coupled to solar energy repository 1300 to charge rechargeable batteries 1308.

Solar energy repository 1300 may be used to provide an extension or elongated version of a solar energy repository operable to remotely couple an electronic device while charging rechargeable batteries 1308. First extension cable 1305 and/or second extension cable 1306 may be provided in various lengths having and wire or conductors with various sized wire gage or diameters to accommodate remote coupling of electronic devices to solar energy repository. For example, rechargeable batteries 1308 and an electronic device needing power may be remotely coupled to solar energy repository 1300 using universal 12-V female receptacle 1303 having an extension 1304. In this manner, solar energy repository 1300 need not be connect to an energy source to couple power to an electronic device. As such, an ‘in-line’ charger or energy repository may be realized.

In one embodiment, solar energy repository 1300 may be used to provide energy to an electronic device without any rechargeable batteries 1308 present within solar energy repository 1300. For example, a user may remove all rechargeable batteries 1308 for use with another electronic device. As such, a user may wish to use solar energy repository 1300 with an electronic device to provide power to an electronic device.

FIG. 14 illustrates a top perspective view of a compact solar energy repository according to one aspect of the invention. A compact solar energy repository, illustrated generally at 1400, includes a housing 1401 to store electronics for charging rechargeable batteries 1406 and coupling converted solar energy to an electronic device (not expressly shown) using universal 12-V female receptacle 1403 and universal 12-V male plug 1402. Compact solar energy repository 1400 includes universal 12-V female receptacle 1403 and universal 12-V male plug 1402 coupled to housing 1401 and provides for compact use and storage of rechargeable batteries 1406. Rechargeable batteries 1406 are housed within rechargeable battery holder 1404 including contacts 1407 arranged such that rechargeable batteries 1406 may be placed with two rechargeable batteries side-by-side and two additional rechargeable batteries placed side-by-side. All four batteries 1406 are aligned in an elongated manner to provide a compact arrangement of rechargeable batteries 1406. Compact solar energy repository 1400 further includes a rechargeable battery holder cover 1405 removeably coupled to housing 1401 and provide access rechargeable batteries 1406. In one embodiment, rechargeable battery holder 1404 may accommodate two or more sizes of batteries (i.e. AA and AAA, etc.) as needed.

During use, a user may couple compact solar energy repository 1400 to a solar energy converter or other power source operable to receive universal 12-V male plug 1402 and provide power to compact solar energy repository 1400 sufficient to charge rechargeable batteries 1406. For example, solar energy may be converted using one or more types of solar energy conversion devices including, but not limited to, one or more portable storage apparatuses illustrated in FIG. 9. Converted solar energy may be coupled to solar energy repository 1400 using universal 12-V male plug 1402 to charge rechargeable batteries 1406.

In another embodiment, solar energy repository 1400 may be configured to couple either end of solar energy repository 1400 to an energy source. For example, either universal 12-V male plug 1402 or universal 12-V female receptacle 1403 may be coupled to an energy source to charge rechargeable batteries 1406 and/or provide power to an electronic device. In this manner, a user may couple either end to a power source without having to use an adapter to couple a specific end to a power source.

Solar energy repository 1400 may also be used in association with conventional power sources to charge rechargeable batteries 1406 and/or power an electronic device. For example, a conventional 12-Volt universal power source provided in association with an automobile, truck, boat, motor home, motorcycle, and the like may be used to charge rechargeable batteries 1406 and/or provide power to an electronic device. For example, a user may connect universal 12-V male plug 1402 into a universal 12-V female receptacle provided as a part of an electrical system of a boat (not expressly shown). As such, a user may utilize energy provided from a direct current power source of the boat to charge rechargeable batteries 1406 and/or provide power to an electronic device thereby providing in-line charging of rechargeable batteries 1406 while providing the flexibility needed to allow users to still use universal 12-V female receptacle 1403 to connect and power electronic devices.

In one embodiment, compact solar power repository 1400 may include an alternating current source plug 1408 and associated electronics to enable coupling an alternating current power source to compact solar power repository 1400 to charge rechargeable batteries 1406 and/or an electronic device. For example, compact solar power repository 1400 may convert AC power to a sufficient DC power to charge batteries 1406. Additionally, compact solar power repository 1400 may disable either one or more DC output ports to reduce the likeliness of electronic shock that may occur if a user contacted universal 12-V male plug 1402, universal 12-V female receptacle 1403, and/or contacts 1407 while connected to an AC power source. In one embodiment, when compact solar power repository 1400 is connected to an AC power source using alternating current source plug 1408, compact solar power repository 1400 may detect when a user connects an electronic device to universal 12-V plug 1402 and/or universal 12-V female receptacle 1403 and enable providing power to an electronic device while disabling the other electrical connections accordingly.

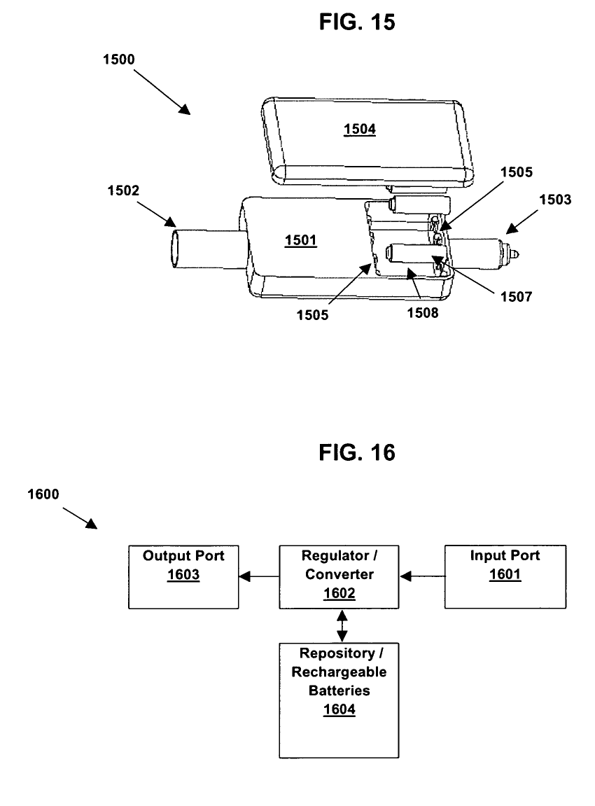

FIG. 15 illustrates a top perspective view of a compact planar solar energy repository according to one aspect of the invention. A planar solar energy repository, illustrated generally at 1500, includes a housing 1501 configured to store electronics for charging rechargeable batteries 1507 and coupling converted solar energy to an electronic device (not expressly shown) using universal 12-V female receptacle 1502 and universal 12-V male plug 1503. Compact solar energy repository 1500 includes 12-V female receptacle 1502 and universal 12-V male plug 1503 coupled to housing 1501 and provides for compact use and storage of rechargeable batteries 1507. Rechargeable batteries 1507 are housed within rechargeable battery holder 1508 including contacts 1505 arranged such that rechargeable batteries 1507 may be placed with four rechargeable batteries side-by-side to provide a planar arrangement of rechargeable batteries 1507 and a substantially flat arrangement for planar solar energy repository 1500. Planar solar energy repository 1500 further includes a rechargeable battery holder cover 1504 removeably coupled to housing 1401 and provide access rechargeable batteries 1507.

During use, a user may couple planar solar energy repository 1500 to a solar energy converter or other power source operable to receive universal 12-V male plug 1503 and provide power to planar solar energy repository 1500 sufficient to charge rechargeable batteries 1507. For example, solar energy may be converted using one or more types of solar energy conversion devices including, but not limited to, one or more portable storage apparatuses illustrated in FIG. 9. Solar energy may be converted and coupled to planar solar energy repository 1500 using universal 12-V female receptacle 1502 to charge rechargeable batteries 1507. In another embodiment, planar solar energy repository 1500 may be configured to couple either end, using either universal 12-V male plug 1503 or universal 12-V female receptacle 1502, to charge rechargeable batteries 1507. In this manner, a user may couple either end or planar solar energy repository 1500 to a power source without having to use an adapter to couple a specific end to a power source.

FIG. 16 illustrates a functional block diagram of an energy repository according to one aspect of the invention. Energy repository, illustrated generally at 1600, includes an input port 1601 coupled to a regulator/converter 1602 operable to convert and regulate energy for energy storage and energy output by energy repository 1600. Energy repository 1600 further includes a repository 1604 which may include various types of energy storage devices operable to store electrical energy for future or current use such as one or more type rechargeable batteries. Energy repository 1600 further includes an output port 1603 operable to output energy to an electronic device.

Input port 1601 may be configured to be coupled to various types of input sources. For example, input port 1601 may include a universal 12-volt male plug operable to be coupled or inserted into a universal 12-volt female receptacle to couple an energy source to energy repository 1600. In another embodiment, input port 1601 may be configured to be coupled to a conventional alternating current power source to provide power to energy repository 1600. One or more types of input ports may be provided to accommodate various types of energy sources.

Regulator/converter 1602 is operable to convert energy coupled to input port 1601 for use. In one embodiment, a user may couple an electronic device to output port 1603 and regulator/converter 1602 may convert and regulate energy which may be provided by repository 1604 and/or input port 1601. For example, repository 1604 may have sufficient energy to power an electronic device and an energy source may not be available to input port 1601. As such, repository 1604 may provide power to output port 1603 via regulator/converter 1602 sufficient to power the electronic device. In another embodiment, a power source may be connected to input port 1601 and repository 1604 may be fully charged. Regulator/converter 1602 may then couple an energy level sufficient to power an electronic device coupled to output port 1603 while maintaining energy stored within repository 1604.

In one embodiment, a power source connected to input port 1601 may not be sufficient to power an electronic device coupled to output port 1603. As such, regulator/converter 1602 may convert and regulate energy (if required) from both input port 1601 and repository 1604 sufficient to power an electronic device. For example, a converted solar energy which is provided through actively converting solar energy using a solar panel (not expressly shown) may not be sufficient to power an electronic device. In this manner, regulator/converter 1603 may provide energy from input port 1601 and determine if the amount of energy is sufficient and provide additional energy from repository 1604 as needed. As such, an energy repository 1600 may provide for active powering of electronic devices based on the needs of an electronic device while using both stored and converted solar energy.

In another embodiment, energy repository 1600 may provide power to an electronic device coupled to output port 1603 while recharging batteries within repository 1604. For example, a power source coupled to input port 1601 having sufficient power to charge batteries within repository 1604 and an electronic device coupled to output port 1603 may be used. In this manner, energy repository 1600 may be used to provide power to an electronic device while charging rechargeable batteries for future use.

Repository/Converter 1602 may also include devices such as current limiting devices such as fuses and blocking diodes may be provided to safely charge the electronic device without risking damage or depleting energy within the electronic device. For example, a blocking diode may be used to eliminate reverse current conditions that may deplete energy stored within a rechargeable battery and/or electronic device. A blocking diode may be provided between output port 1603 and regulator/converter 1602 to obviate undesired reverse current conditions. Similarly, a blocking diode may be provided between input port 1601 and regulator/converter 1602 to obviate undesired reverse current conditions. In this manner, energy repository 1600 and an electronic device may be protected from undesired operating conditions.

Although the disclosed embodiments have been described in detail, it should be understood that various changes, substitutions and alterations can be made to the embodiments without departing from their spirit and scope.

1. An apparatus for charging an electronic device comprising:
a first charge port operable to be connected to an energy source;
an energy repository operable to store energy provided by the energy source and to actively couple energy provided by the energy source to an electronic device; and
a second charge port operable to be connected to the electronic device to provide either the stored energy or the active energy to the electronic device.

2. The apparatus of claim 1 further comprising the energy repository only provides energy to the electronic device.

3. The apparatus of claim 2 wherein the energy repository comprises rechargeable batteries.

4. The apparatus of claim 1 further comprising the second charge port operable to connect the stored energy and the active energy to the electronic device.

5. The apparatus of claim 1 further comprising the charge port operable to simultaneously connect the stored energy and the active energy to the electronic device.

6. The apparatus of claim 1 further comprising:
a universal twelve-volt female charge port including an female charge port extension cable; and
a universal twelve-volt male charge port including a male charge port extension cable.

7. The apparatus of claim 1 further comprising a battery holder arranged to hold a first pair of rechargeable batteries along side of a second pair of rechargeable batteries and to couple the energy to the rechargeable batteries to charge the batteries.

8. The apparatus of claim 1 further comprising a battery holder arranged to hold a first pair of rechargeable batteries in front of a second pair of rechargeable batteries and to couple the energy to the rechargeable batteries to charge the batteries.

9. The apparatus of claim 1 further comprising an alternating current plug coupled to the repository and operable to couple an alternating current charge source to the repository.

10. An apparatus for charging an electronic device comprising:
a first charge port operable to couple an electronic device to an energy source; and
a housing including electronics operable to couple the energy source to an energy repository and the electronic device.

11. The apparatus of claim 1 further comprising the first charge port extended away from the housing and operable to couple energy to the electronic device.

12. The apparatus of claim 1 further comprising the first charge port directly coupled to the housing and operable to couple energy to the electronic device.

13. The apparatus of claim 1 further comprising:
a second charge port operable to couple a solar energy power source to the first charge port; and
a charge circuit provided within the housing and operable to couple the solar energy to at least one rechargeable battery and the electronic device.

14. The apparatus of claim 13 further comprising:
a portable storage apparatus including a removable solar panel couple to a solar panel holder integrated as a part of an exterior portion of the portable storage apparatus; and
a charge port operable to interface at least one of the first charge port or the second charge port and operable to provide the energy.

15. The apparatus of claim 13 further comprising a solar panel holder integrated as a part of an exterior portion of the apparatus to house the removable solar panel.

16. The apparatus of claim 14 wherein the solar panel holder comprises:
a first cavity operable to house the solar panel holder;
an aperture provided as a position of the exterior and coupled to the first cavity, the aperture operable to expose a portion of the removable solar panel; and
an access interface operable to provide access to the removable solar panel.

17. The apparatus of claim 16 further comprising a charge port directly coupled to the removable solar panel.

18. A portable energy repository operable to charge an electronic device comprising:
a solar energy panel interface operable to couple converted solar energy to an electronic device; and
a rechargeable energy repository having at least one rechargeable battery operable to charge a first electronic device and a charge port operable to couple the converted solar energy to a second electronic device.

19. The apparatus of claim 18 further comprising:
solar panel holder means for retaining a removable solar panel; and
removable battery holder means for coupling the converted solar energy to the at least one rechargeable battery.

20. The apparatus of claim 18 further comprising a compact housing operable to house electronics of the rechargeable energy repository including the at least one rechargeable battery.
